(19) United States
(12) Patent Application Publication
(10) Pub. No.: US 2026/0095982 A1
(43) Pub. Date: Apr. 2, 2026

(54) SUSCEPTOR FOR PROCESSING SUBSTRATES

(71) Applicant: ASM IP Holding B.V., Almere (NL)

(72) Inventors: Jun Kurano, Tokyo (JP); DaeYoun Kim, Seo-gu (KR); Dave Silvetti, Fountain Hills, CA (US); Gopu Krishna, Hwaseong-si (KR); Koei Aida, Tokyo (JP); Jun Yoshikawa, Tokyo (JP)

(21) Appl. No.: 19/339,528

(22) Filed: Sep. 25, 2025

Related U.S. Application Data
(60) Provisional application No. 63/701,205, filed on Sep. 30, 2024.

(51) Int. Cl. H05B 6/10; H01L 21/683

(52) U.S. Cl. CPC H05B 6/105; H10P 72/722; H05B 2213/07

(57) ABSTRACT

A susceptor with ESC functionality is presented. To provide a heater with metal material for thermal control and ESC capabilities, the present disclosure's susceptor comprises a supporting part configured to support a substrate, a heating coil disposed in the supporting part, the heating coil configured to heat up the temperature of the support, a thermocouple (TC) disposed in the supporting part for monitoring temperature of the supporting part, a shaft disposed below the supporting part, an insulation part disposed in the shaft, a plurality of cooling channels disposed in the insulation part; and insulation layers disposed on the surface of the supporting part and the insulating part, wherein the supporting part is made of conducting metals.

### CROSS-REFERENCE TO RELATED APPLICATIONS

This application claims priority to U.S. Provisional Patent Application Ser. No. 63/701,205 filed Sep. 30, 2024 titled SUSCEPTOR FOR PROCESSING SUBSTRATES, the disclosure of which is hereby incorporated by reference in its entirety.

### FIELD OF INVENTION

The present disclosure relates generally to a susceptor used in semiconductor manufacturing, more particularly to a metal susceptor with an electrostatic chucking capabilities.

### BACKGROUND OF THE DISCLOSURE

Conventionally, when an AlN susceptor heater is used in a low-temperature process, cooling performance during deposition becomes insufficient and the heater surface temperature cannot be controlled. This may cause a temperature rise of the wafer and it may lead to a lower film quality and throughput.

When Aluminum susceptor heater is used in such low-temperature processes, it is difficult to add the electrostatic chucking (ESC) function, and the cooling performance is insufficient under high-power conditions, so wafer temperature rises during film deposition.

Therefore, the present disclosure provides a new susceptor with thermal control and ESC functions.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a susceptor for processing substrates, the susceptor comprises: a supporting part configured to support a substrate; a heating coil disposed in the supporting part, the heating coil configured to heat up the temperature of the support; a thermocouple (TC) disposed in the supporting part for monitoring temperature of the supporting part; a shaft disposed below the supporting part; an insulation part disposed in the shaft; a plurality of cooling channels disposed in the insulation part; and insulation layers disposed on the surface of the supporting part and the insulating part, wherein the supporting part is made of conducting metals.

In an aspect, the susceptor further comprising a heating power source connected to the heating coil and configured to supply power for the heating coil to heat up; and a chucking power source connected to the supporting part and configured to supply power for providing electrostatic chucking (ESC) function to the supporting part.

In an aspect, the conducting metals comprises one of the Copper (Cu), Aluminum (Al), Iron (Fe), Zinc (Zn), Nickel (Ni), Tungsten (W) and Tin (Sn) or a mixture thereof.

In an aspect, the susceptor further comprising a TC tube disposed from the TC to a bottom of the insulation part and contains a TC line which electrically connects the TC and the sensor; a heat tube disposed from the heating coil to the bottom of the insulating part and contains a heat line which electrically connects the heating coil and the heating power source; a chuck tube disposed from the supporting part to the bottom of the insulating part and contains a heat line which electrically connects the supporting part and the chucking power source; and a pair of cooling tubes for supplying and exiting coolant to the cooling channels respectively.

In an aspect, the heating power source further comprising: an alternating current (AC) transformer for generating power; and a thyristor connected to the AC transformer at one side and to the heating coil.

In an aspect, the chucking power source further comprising: a power generator; and a resistor configured to cut out radio frequency (RF) element, wherein the power generator is connected to an earth, and the power generator and the resistor are connected in series.

In an aspect, a capacitor is connected in parallel to the power generator and the resistor and the capacitor is connected to another earth.

In an aspect, the TC tube, the heat tube, the chuck tube and the cooling tubes are coated with insulating materials.

In accordance with another embodiment there may be provided, a susceptor for processing substrates, the susceptor comprises: a supporting part configured to support a substrate; a heating coil disposed in the supporting part, the heating coil configured to heat up the temperature of the support; a thermocouple (TC) disposed in the supporting part for monitoring temperature of the supporting part; a plurality of cooling channels disposed in the supporting part; a shaft disposed below the supporting part; an insulation part disposed below the shaft; an adaptor disposed below the insulation part; and insulation layers disposed on the surface of the supporting part, the insulating part, and the adaptor, wherein the supporting part is made of conducting metals.

In an aspect, the susceptor further comprising a heating power source connected to the heating coil and configured to supply power for the heating coil to heat up; and a chucking power source connected to the supporting part and configured to supply power for providing electrostatic chucking (ESC) function to the supporting part.

In an aspect, the conducting metals comprises one of the Copper (Cu), Aluminum (Al), Iron (Fe), Zinc (Zn), Nickel (Ni), Tungsten (W) and Tin (Sn) or a mixture thereof.

In an aspect, the susceptor further comprising a TC tube disposed from the TC to a bottom of the insulation part and contains a TC line which electrically connects the TC and the sensor; a heat tube disposed from the heating coil to the bottom of the insulating part and contains a heat line which electrically connects the heating coil and the heating power source; a chuck tube disposed from the supporting part to the bottom of the insulating part and contains a heat line which electrically connects the supporting part and the chucking power source; and a pair of cooling tubes for supplying and exiting coolant to the cooling channels respectively.

In an aspect, the heating power source further comprising: an alternating current (AC) transformer for generating power; and a thyristor connected to the AC transformer at one side and to the heating coil.

In an aspect, the chucking power source further comprising: a power generator; and a resistor configured to cut out radio frequency (RF) element, wherein the power generator is connected to an earth, and the power generator and the resistor are connected in series.

In an aspect, a capacitor is connected in parallel to the power generator and the resistor and the capacitor is connected to another earth.

In an aspect, the TC tube, the heat tube, the chuck tube and the cooling tubes are coated with insulating materials.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an overview of a susceptor according to an embodiment of the present disclosure.

FIG. 2 illustrates an overview of a susceptor according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

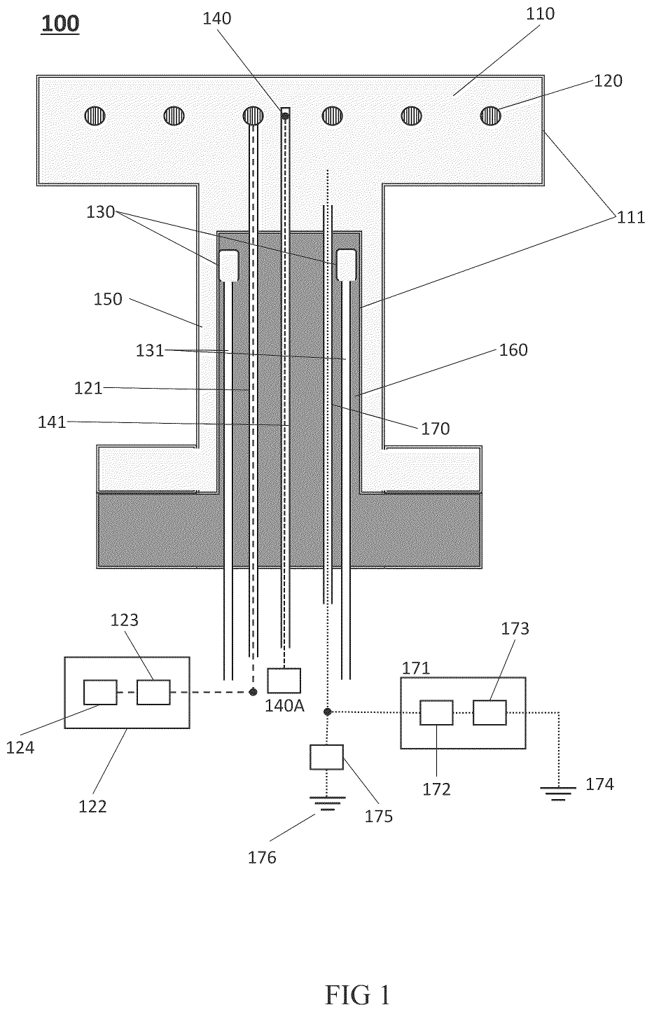

FIG. 1 illustrates a susceptor for processing substrates according to an embodiment of the present disclosure. The susceptor 100 may comprise a supporting part 110, a heating coil 120, a shaft 150, and an insulation part 160.

The supporting part 110 may be made of conducting materials such metals as Copper (Cu), Aluminum (Al), Iron (Fe), Zinc (Zn), Nickel (Ni), Tungsten (W) and Tin (Sn) or a mixture of one or more of them.

In the supporting part 110, heating coil 120 and a thermocouple (TC) 140 may be located. The heating coil 120 is used to heat up the support part 110 during substrate processing and the TC 140 may be used to monitor the temperature of the supporting part 110.

For cooling down the supporting part 110, coolant may be used in the coolant channels 130. However, if water is used as coolant, the water would be evaporated in the coolant channel 130 if the coolant channel 130 is located near to the heating coil 120. For a case when water is used as coolant, the coolant channel 130 is placed in the insulation part 160 like in FIG. 1 so that the coolant may not be evaporated. The insulation part 160 may be placed somewhat far from the heating coil 120 and the coolant channel 130 may be separated from the supporting part 110.

Coolant may be provided to the coolant channel 130 by way of cooling tube 131 and the TC tube 141 may protect the TC 140 and the link between the TC 140 and the sensor 140A which is used to monitor the temperature of the supporting part 110.

The heating coil 120 may be connected to the heating power source 122 and the connection is protected by heat tube 121 from the heating coil 120 to the bottom of the insulating part 160. The heating power source 122 may comprise an alternating current (AC) transformer 124 for power generation and a thyristor 123 for rectifying the power input from the transformer 124.

As mentioned above, the supporting part 110 may be made from conductive metal or metals for electrostatic chuck (ESC) functionality. For ESC, the supporting part 110 may be connected to a chucking power source 171 and this connection may be protected by a chuck tube 170. The chuck power source 171 may comprise a power generator 173 and a resistor 172 connected in series and the resistor 172 may be used to cut off a radio frequency (RF) element transmitted.

A capacitor 175 may be connected in parallel to the power generator 173 and the resistor 172 and may be connected to an earth 176 and the capacitor may be used to isolate the direct current (DC) in the supporting part 110.

An insulation layer 111 may be covered on the surface of the supporting part 110, the shaft 150 and also the insulation part 160. The insulation layers 111 may provide an ESC function to the supporting part 110. Also, the surfaces of the tubes, i.e., TC tube 141, cooling tubes 131, heat tube 121 and chuck tube 170 may be coated with insulating materials.

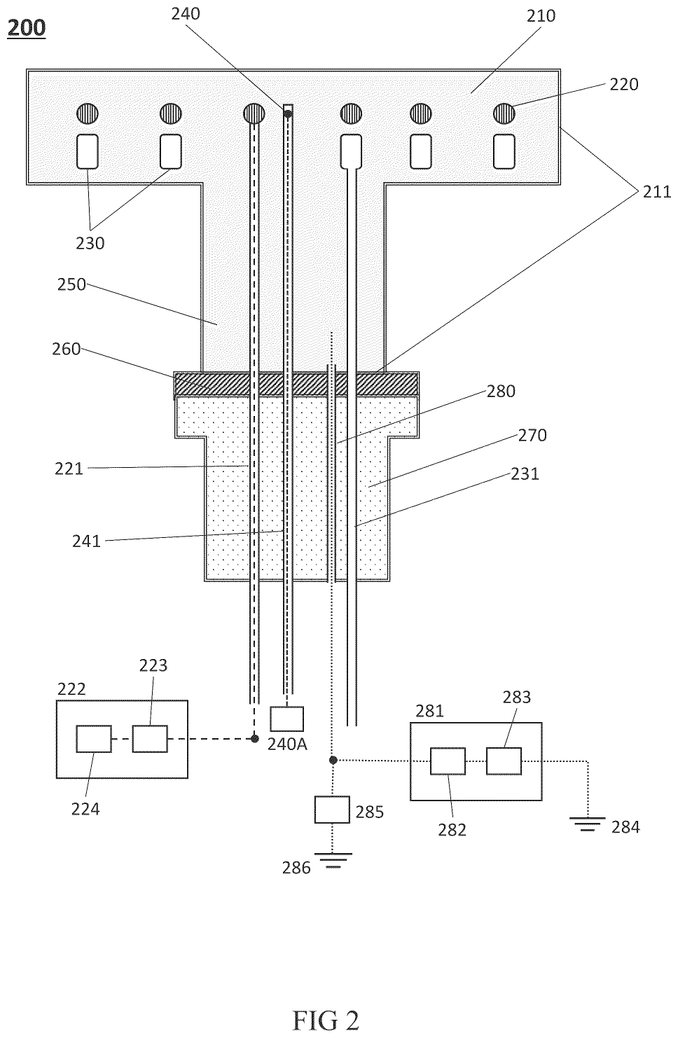

FIG. 2 illustrates a susceptor for processing substrates according to another embodiment of the present disclosure. The susceptor 200 may comprise a supporting part 210, a heating coil 220, a shaft 250, and an insulation part 260 and an adaptor 270.

The supporting part 210 may be made of conducting materials such metals as Copper (Cu), Aluminum (Al), Iron (Fe), Zinc (Zn), Nickel (Ni), Tungsten (W) and Tin (Sn) or a mixture of one or more of them.

In the supporting part 210, heating coil 220 and a thermocouple (TC) 240 may be located. The heating coil 220 is used to heat up the supporting part 210 during substrate processing and the TC 240 may be used to monitor the temperature of the supporting part 210.

For cooling down the supporting part 210, coolant may be used in the coolant channels 230. In FIG. 2, a coolant with higher boiling point (than water) may be used so the evaporation problem may not occur. Therefore, the coolant channel 230 is placed in the supporting part 210 like in FIG. 2. The insulation part 260 may be placed somewhat in the shaft 250 to provide electrical insulation from the supporting part 210.

Coolant may be provided to the coolant channel 230 by way of cooling tube 231 and the TC tube 241 may protect the TC 240 and the link between the TC 240 and the sensor 240A which is used to monitor the temperature of the supporting part 210.

The heating coil 220 may be connected to the heating power source 222 and the connection is protected by heat tube 221 from the heating coil 220 to the bottom of the adaptor 270. The heating power source 222 may comprise an alternating current (AC) transformer 224 for power generation and a thyristor 223 for rectifying the power input from the transformer 224.

As mentioned above, the supporting part 210 may be made from conductive metal or metals for electrostatic chuck (ESC) functionality. For ESC, the supporting part 210 may be connected to a chucking power source 281 and this connection may be protected by a chuck tube 280. The chuck power source 281 may comprise a power generator 283 and a resistor 282 connected in series and the resistor 282 may be used to cut off a radio frequency (RF) element transmitted.

A capacitor 285 may be connected in parallel to the power generator 283 and the resistor 282 and may be connected to an earth 286 and the capacitor may be used to isolate the direct current (DC) in the supporting part 210.

An insulation layer 211 may be covered on the surface of the supporting part 210, the shaft 250 and also the insulation part 260. The insulation layer 211 may provide an ESC function to the supporting part 210. Also, the surfaces of the tubes, i.e., TC tube 241, cooling tubes 231, heat tube 221 and chuck tube 280 may be coated with insulating materials.

The susceptors 100, 200 with metal supporting part 110. 210 with insulation layer 111, 211 according to the present disclosure may make it efficient to control the temperature during substrate processing because it has a metal (i.e., very conductive) body and may also provide an ESC capabilities.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A susceptor for processing substrates, the susceptor comprises:
a supporting part configured to support a substrate;
a heating coil disposed in the supporting part, the heating coil configured to heat up the temperature of the support;
a thermocouple (TC) disposed in the supporting part for monitoring temperature of the supporting part;
a shaft disposed below the supporting part;
an insulation part disposed in the shaft;
a plurality of cooling channels disposed in the insulation part; and
insulation layers disposed on the surface of the supporting part and the insulating part, wherein the supporting part is made of conducting metals.

2. A susceptor according to claim 1, further comprising
a heating power source connected to the heating coil and configured to supply power for the heating coil to heat up; and
a chucking power source connected to the supporting part and configured to supply power for providing electrostatic chucking (ESC) function to the supporting part.

3. A susceptor according to claim 1, wherein
the conducting metals comprises one of the Copper (Cu), Aluminum (Al), Iron (Fe), Zinc (Zn), Nickel (Ni), Tungsten (W) and Tin (Sn) or a mixture thereof.

4. A susceptor according to claim 1, further comprising
a TC tube disposed from the TC to a bottom of the insulation part and contains a TC line which electrically connects the TC and the sensor;
a heat tube disposed from the heating coil to the bottom of the insulating part and contains a heat line which electrically connects the heating coil and the heating power source;
a chuck tube disposed from the supporting part to the bottom of the insulating part and contains a heat line which electrically connects the supporting part and the chucking power source; and
a pair of cooling tubes for supplying and exiting coolant to the cooling channels respectively.

5. A susceptor according to claim 2, the heating power source further comprising:
an alternating current (AC) transformer for generating power; and
a thyristor connected to the AC transformer at one side and to the heating coil.

6. A susceptor according to claim 2, the chucking power source further comprising:
a power generator; and
a resistor configured to cut out radio frequency (RF) element,
wherein the power generator is connected to an earth, and
the power generator and the resistor are connected in series.

7. A susceptor according to claim 6, wherein a capacitor is connected in parallel to the power generator and the resistor and the capacitor is connected to another earth.

8. A susceptor according to claim 4, wherein the TC tube, the heat tube, the chuck tube and the cooling tubes are coated with insulating materials.

9. A susceptor for processing substrates, the susceptor comprises:
a supporting part configured to support a substrate;
a heating coil disposed in the supporting part, the heating coil configured to heat up the temperature of the support;
a thermocouple (TC) disposed in the supporting part for monitoring temperature of the supporting part;
a plurality of cooling channels disposed in the supporting part;
a shaft disposed below the supporting part;
an insulation part disposed below the shaft;
an adaptor disposed below the insulation part; and
insulation layers disposed on the surface of the supporting part, the insulating part, and the adaptor, wherein the supporting part is made of conducting metals.

10. A susceptor according to claim 9, further comprising
a heating power source connected to the heating coil and configured to supply power for the heating coil to heat up; and
a chucking power source connected to the supporting part and configured to supply power for providing electrostatic chucking (ESC) function to the supporting part.

11. A susceptor according to claim 9, wherein
the conducting metals comprises one of the Copper (Cu), Aluminum (Al), Iron (Fe), Zinc (Zn), Nickel (Ni), Tungsten (W) and Tin (Sn) or a mixture thereof.

12. A susceptor according to claim 9, further comprising
a TC tube disposed from the TC to a bottom of the insulation part and contains a TC line which electrically connects the TC and the sensor;
a heat tube disposed from the heating coil to the bottom of the insulating part and contains a heat line which electrically connects the heating coil and the heating power source;
a chuck tube disposed from the supporting part to the bottom of the insulating part and contains a heat line which electrically connects the supporting part and the chucking power source; and
a pair of cooling tubes for supplying and exiting coolant to the cooling channels respectively.

13. A susceptor according to claim 10, the heating power source further comprising:
an alternating current (AC) transformer for generating power; and
a thyristor connected to the AC transformer at one side and to the heating coil.

14. A susceptor according to claim 10, the chucking power source further comprising:
a power generator; and
a resistor configured to cut out radio frequency (RF) element,
wherein the power generator is connected to an earth, and
the power generator and the resistor are connected in series.

15. A susceptor according to claim 14, wherein a capacitor is connected in parallel to the power generator and the resistor and the capacitor is connected to another earth.

16. A susceptor according to claim 12, wherein the TC tube, the heat tube, the chuck tube and the cooling tubes are coated with insulating materials.
